(19) United States
(12) Patent Application Publication
(10) Pub. No.: US 2008/0144269 A1
(43) Pub. Date: Jun. 19, 2008

(54) Computer chassis

(76) Inventor: Matthew Murtha, New York, NY (US)

Correspondence Address: DAY PITNEY LLP, 7 TIMES SQUARE, NEW YORK, NY, 10036-7311, US

(21) Appl. No.: 11/639,925

(22) Filed: Dec. 15, 2006

(51) Int. Cl. H05K 5/02

(52) U.S. Cl. 361/683

(57) ABSTRACT

A computer chassis, specifically a box-like container in which computer components are installed to assemble a computer, has a top, a bottom, a left side and a right side, a rear and an open front. The top and bottom are formed of top and bottom members, respectively. At least a portion of the left and right sides is formed by left and right members, respectively. A motherboard member forms a portion of one of the left and right sides. Finally, the rear is formed by a rear member. The top, bottom, left, right, motherboard and rear members are of sheet material, at least one of which is a lattice member including open areas which make up a substantial portion of the total area of the lattice member.

### BACKGROUND OF THE INVENTION

1. Field of the Invention

The present invention relates to the field of computer hardware. More specifically, the present invention is a computer chassis in which computer components may be installed to assemble a computer.

2. Description of the Prior Art

Computer chassis are well known in the art. Generally, such chassis are in the form of box-like containers having open fronts. The top, bottom, left, right and rear walls generally have minimal openings, except those adjacent to fans provided for cooling and ventilation.

In recent years, computer enthusiasts, perhaps not completely satisfied with the features available in computers currently on the market or eager to improve their performance and appearance, have begun to build computers of their own design using components available on the market. Quite often, the enthusiasts cut holes into the chassis of the prior art, and install lights and auxiliary fans within the chassis along with the computer components to create interesting visual effects and to increase airflow and cooling ability.

The present invention is a computer chassis designed to meet the needs of this new generation of computer enthusiasts, who are interested not only in designing their own computers having features, such as increased speed or memory space, not available in off-the-shelf models, but also in equipping them with exciting visual effects, as well as in providing them with ample cooling options.

### SUMMARY OF THE INVENTION

Accordingly, the present invention is a computer chassis in the form of a box-like container wherein computer components are installed and connected with one another to assemble a computer. The computer chassis has a top, a bottom, a left side, a right side, a rear and an open front.

The computer chassis comprises a top member which forms the top thereof, and a bottom member which forms the bottom thereof. At least a portion of the left and right sides are formed by a left member and right member, respectively. Together with the top and bottom members, the left and right members frame the open front of the computer chassis.

A motherboard member forms a portion of one of the left and right sides of the computer chassis, and is so-called because it is where the motherboard of the computer to be assembled may be mounted.

The rear is formed by a rear member which may or may not be integrally formed with the motherboard member.

The top, bottom, left, right, motherboard and rear members are all of sheet material, perhaps aluminum or plastic. At least one of these members is a lattice member which includes a plurality of open areas making up a substantial portion of the total area of the lattice member.

The present invention will now be described in more complete detail with frequent reference being made to the drawing figures identified below.

### BRIEF DESCRIPTION OF THE DRAWINGS

FIG. 1 is a perspective view of the computer chassis of the present invention, taken from in front and to the left thereof;

FIG. 2 is an enlarged perspective view of the lower front of the computer chassis, taken from in front and to the right thereof;

FIG. 3 is a perspective view of the computer chassis, taken from in front and to the right thereof;

FIG. 4 is an elevational view of the right side of the computer chassis 10;

FIG. 5 is a perspective view of the computer chassis taken from behind and to the right thereof;

FIG. 6 is a perspective view of the left side of the computer chassis;

FIG. 7 is an elevational view straight into the front thereof;

FIG. 8 is an elevational view taken from above the computer chassis;

FIG. 9 is a perspective view of a computer including the computer chassis of the present invention from above and to the right thereof;

FIG. 10 is an elevational view of the right side of the computer;

FIG. 11 is an elevational view of the left side of the computer;

FIG. 12 is a perspective view of the computer 100 from above and to the left thereof;

FIG. 13 is an elevational view of the top lattice member of the computer chassis; and

FIG. 14 is an elevational view of the left lattice member thereof.

### DETAILED DESCRIPTION OF THE PREFERRED EMBODIMENT

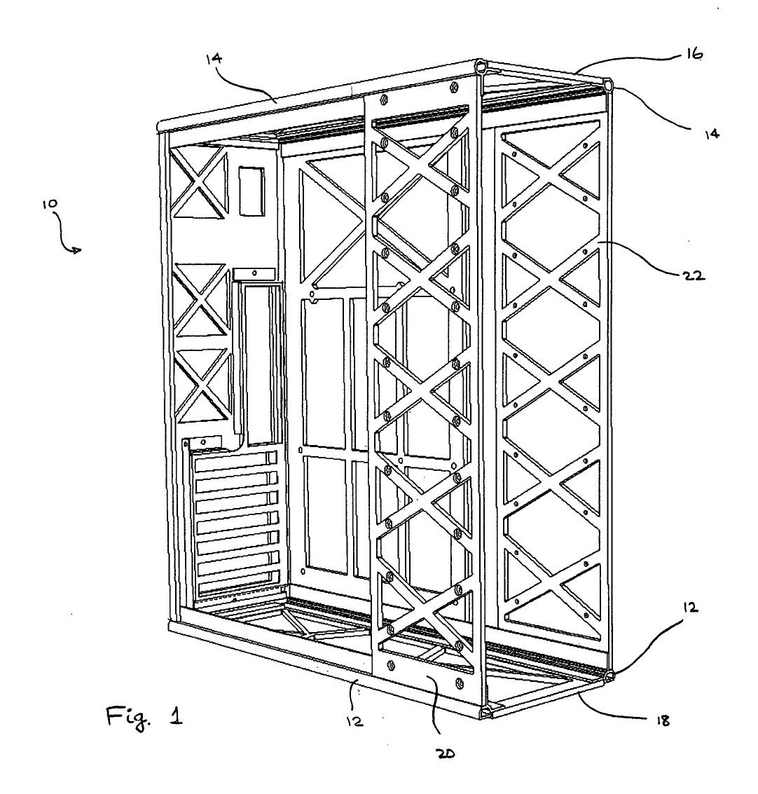

Referring now to these figures, FIG. 1 is a perspective view of the computer chassis 10 of the present invention. The computer chassis 10 comprises two lower frame members 12, two upper frame members 14, a top lattice member 16, a bottom lattice member 18. The perspective view shown in FIG. 1 is taken from in front and to the left of the computer chassis 10. A left lattice member 20 and a right lattice member 22, together with the lower frame members 12, upper frame members 14, top lattice member 16 and bottom lattice member 18, define and frame a front opening through which a user may install computer components within the computer chassis 10 in order to assemble a computer of his or her own design.

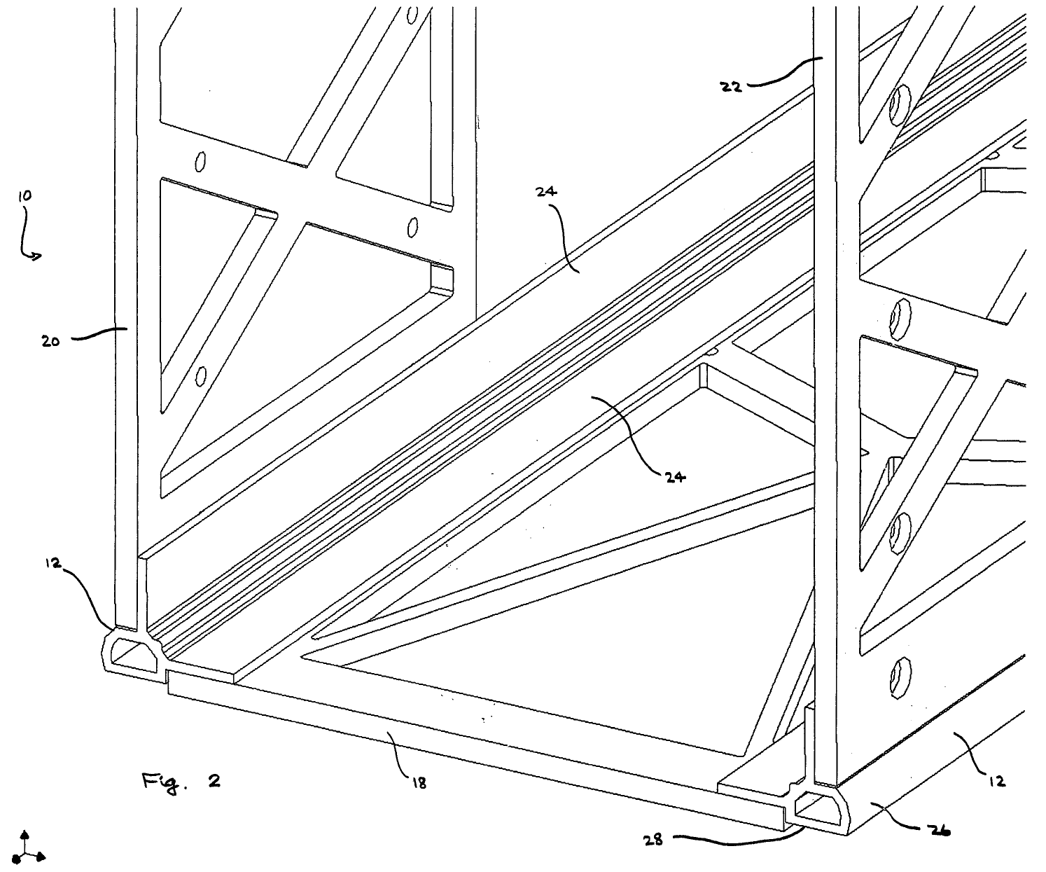

FIG. 2 is an enlarged perspective view of the lower front of the computer chassis 10 taken from in front and to the right thereof. Lower frame members 12 may be extruded from a metallic or plastic material, preferably aluminum. The elongated lower frame members 12 include a pair of fins 24 extending substantially at right angles to one another from base 26 which may be hollow in the interests of reduced cost without sacrificing structural integrity. Base 26 has a flattened bottom side 28, so that base 26 does not extend below bottom lattice member 18 when computer chassis 10 is standing upright as shown in FIGS. 1 and 2.

Fins 24 adjacent to flattened bottom sides 28 of lower frame members 12 are attached to opposite sides of bottom lattice member 18. The other fins 24 then extend perpendicularly upward from bases 26, and are attached to left and right lattice members 20, 22. The attachment may be by any means conventional in the art. Where bottom lattice member 18 and left and right lattice members 20, 22 are produced from punched aluminum sheet material, as may be the case, the attachment may be by screws, rivets, spot welding or the like.

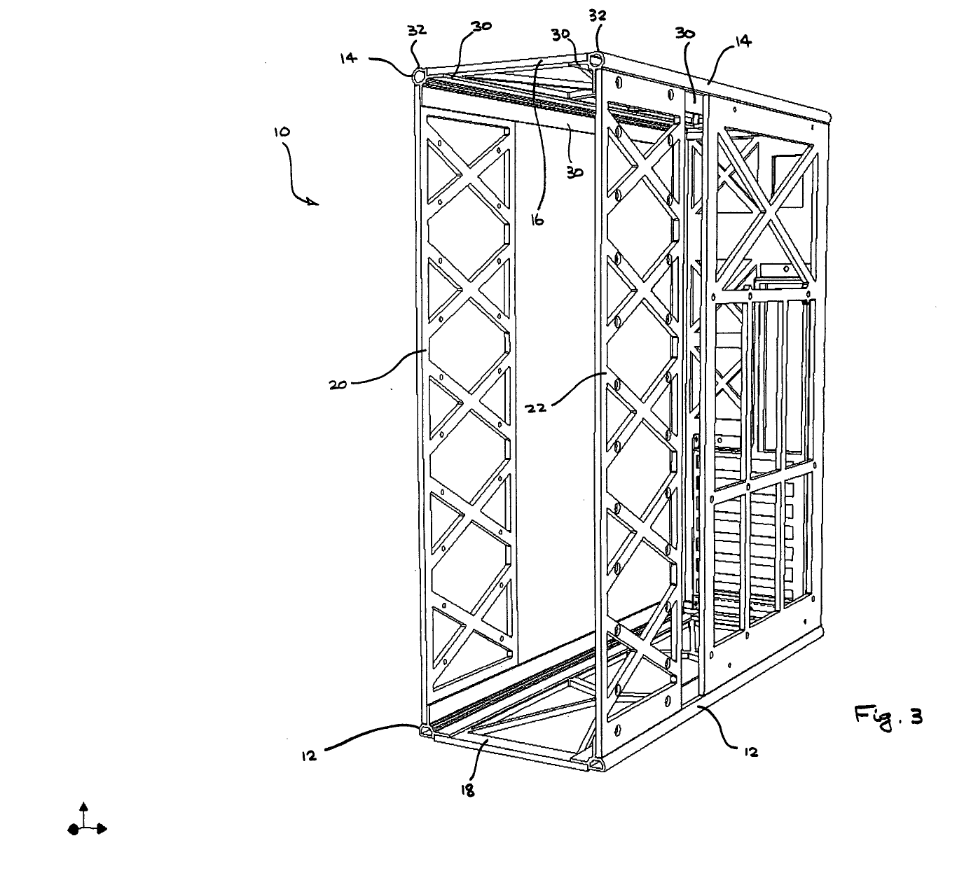

FIG. 3 is a perspective view of the computer chassis 10 taken from in front and to the right thereof. Referring to the top portion of FIG. 3, the elongated upper frame members 14 also include two fins 30 extending at substantially right angles to one another from base 32 which may also be hollow to reduce material costs without sacrificing structural integrity. Base 32 is rounded, and lacks the flattened bottom portion 28 of the base 26 of the lower frame members 12. Upper frame members 14 may be extruded from a metallic or plastic material, preferably aluminum.

One fin 30 on the upper frame members 14 is attached to the left lattice member 20 or to the right lattice member 22. The other fins 30 then extend toward each other from the upper frame members 14 on the right and left sides of the computer chassis 10. Top lattice member 16 is attached to these other fins by conventional means. Top lattice member 16, like the other lattice members 18, 20, 22, may be produced from punched aluminum sheet material. In such case, the attachment may be by the means described above.

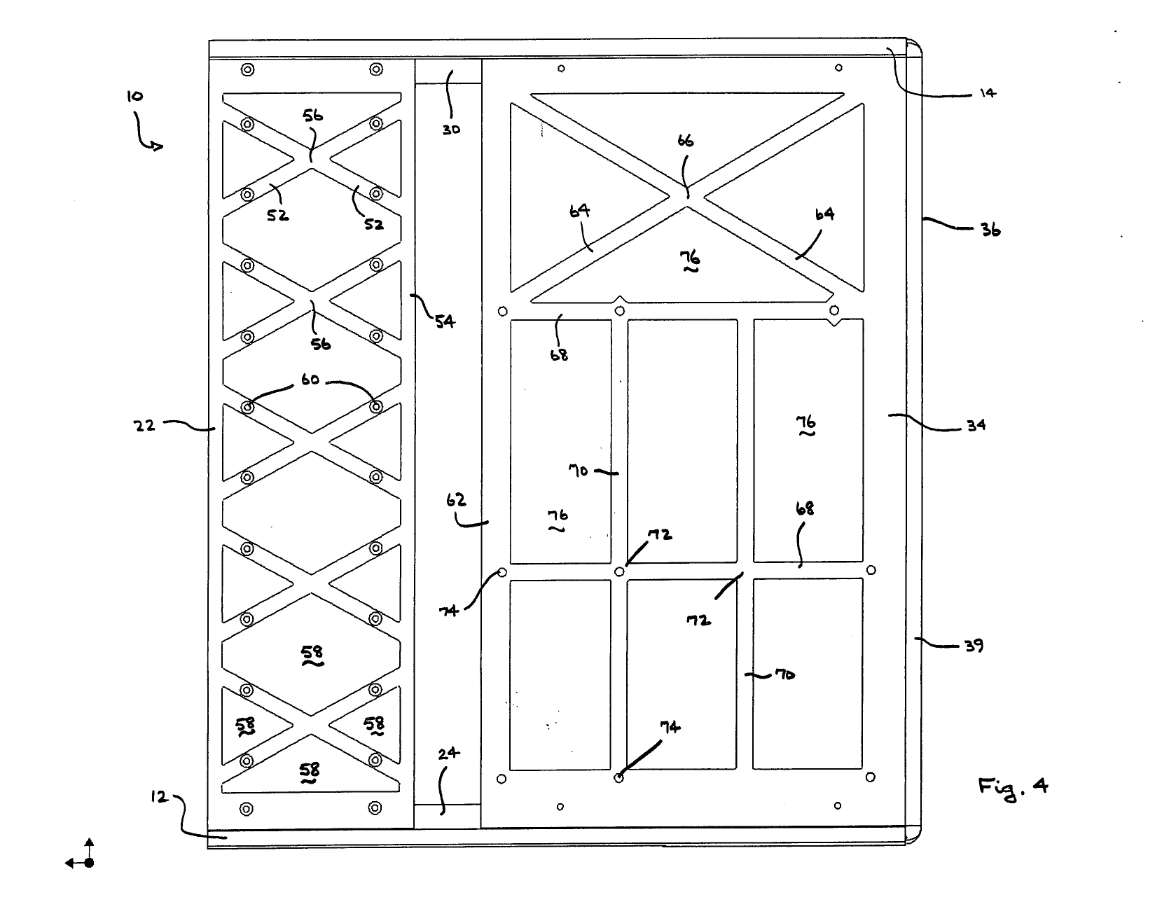

FIG. 4 is an elevational view of the right side of the computer chassis 10. In addition to right lattice member 22, the right side of the computer chassis 10 includes a motherboard lattice member 34, on which the motherboard for the computer to be assembled within the computer chassis 10 may be mounted. As was the case with the right lattice member 22, the motherboard lattice member 34 is attached to fin 30 of upper frame member 14 and to fin 24 of lower frame member 12 by conventional means. Motherboard lattice member 34 may also be produced from punched aluminum sheet material. In such a case, the attachment may be by the means described above. It will be apparent to those of ordinary skill in the art that the right lattice member 22 and the motherboard lattice member 34 may be integrally formed with one another.

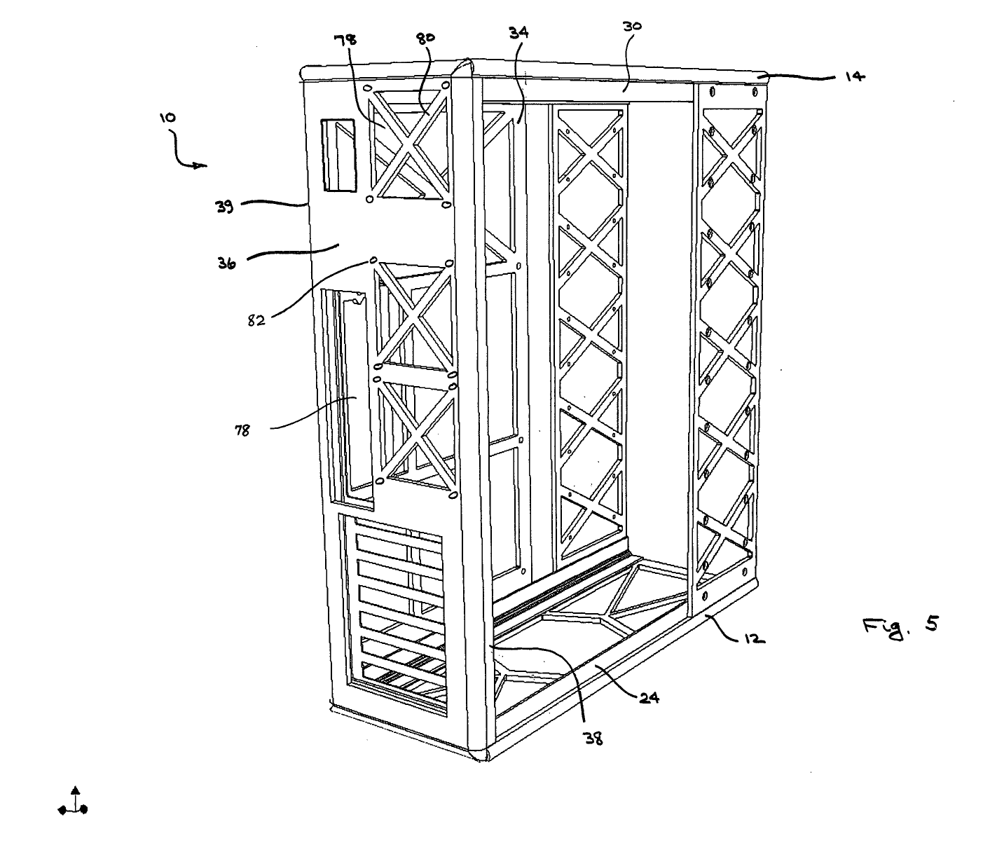

FIG. 5 is a perspective view of the computer chassis 10 taken from behind and to the right thereof, showing rear lattice member 36. Rear lattice member 36 may be integrally formed with motherboard lattice member 34, and is substantially planar, but has a vertically oriented edge 38 which is curved or bent into a direction perpendicular to the plane thereof opposite to the motherboard lattice member 34. Edge 38 is attached to fin 30 of upper frame member 14 and to fin 24 of lower frame member 12 in the view shown in FIG. 5 by conventional means, such as those described above. On the right side of the computer chassis 10, as shown in FIG. 4, motherboard lattice member 34 and rear lattice member 36, which may be integrally formed with one another, are separated from one another by curved or bent corner 39 such that motherboard lattice member 34 and rear lattice member 36 are substantially perpendicular to one another. The attachment of motherboard lattice member 34 to fin 30 of upper frame member 14 and to fin 24 of lower frame member 12 opposite to edge 38 secures rear lattice member 36 to the lower and upper frame members 12, 14.

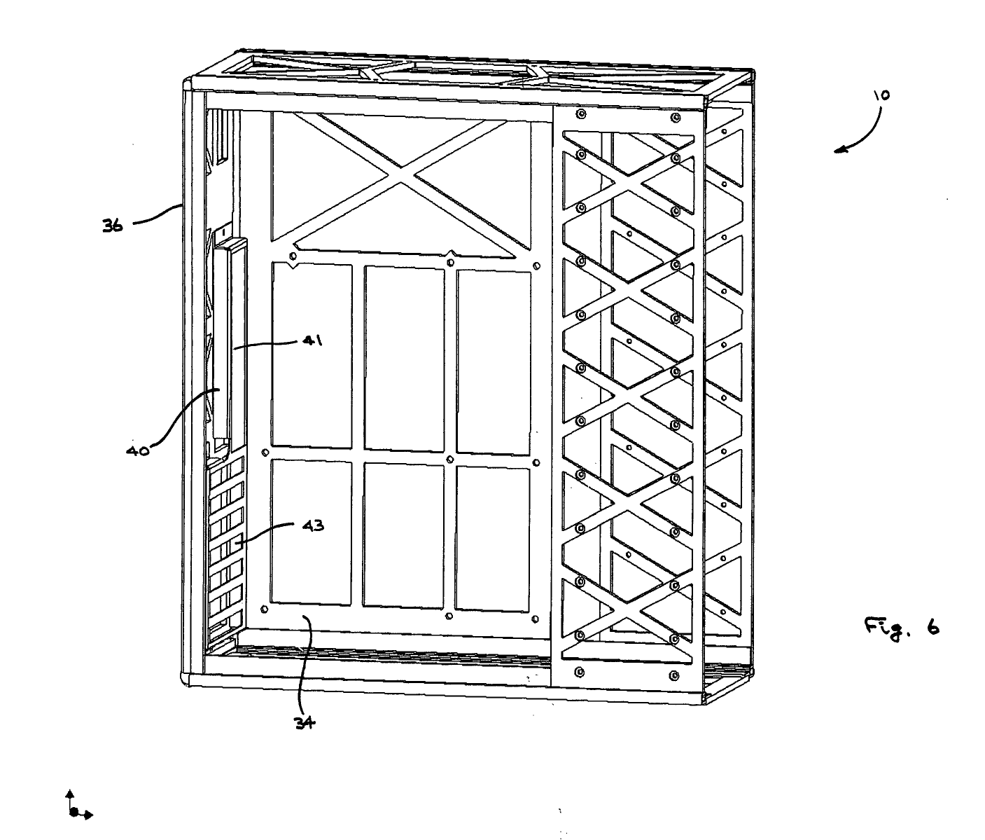

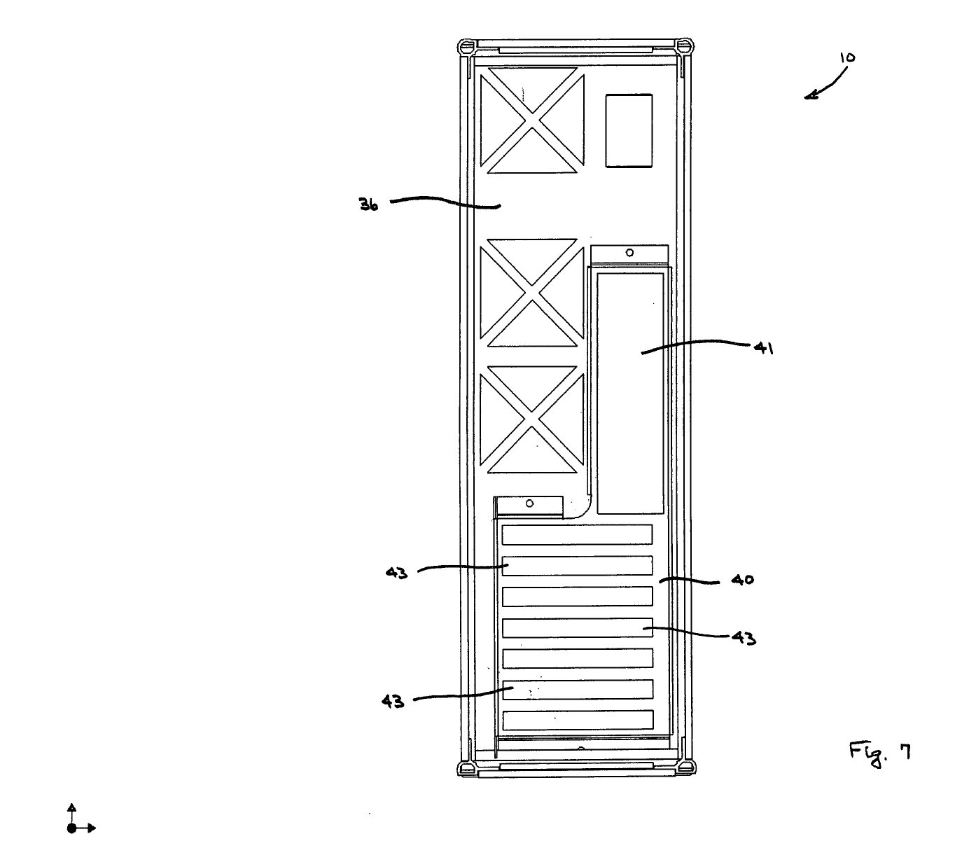

FIGS. 6 and 7 show details of the inside surface of the rear lattice member 36 of the computer chassis 10. FIG. 6 is a perspective view of the left side of the computer chassis 10, and FIG. 7 is an elevational view straight into the front thereof. As may best be seen in FIG. 6, mounting element 40 is attached to the inside of the rear lattice member 36 to provide support for the motherboard and memory boards to be attached to the motherboard lattice member 34. FIG. 7 shows a clearer view of mounting element 40 directly from the front. Mounting element 40 includes motherboard input/output slot 41 and expansion slots 43.

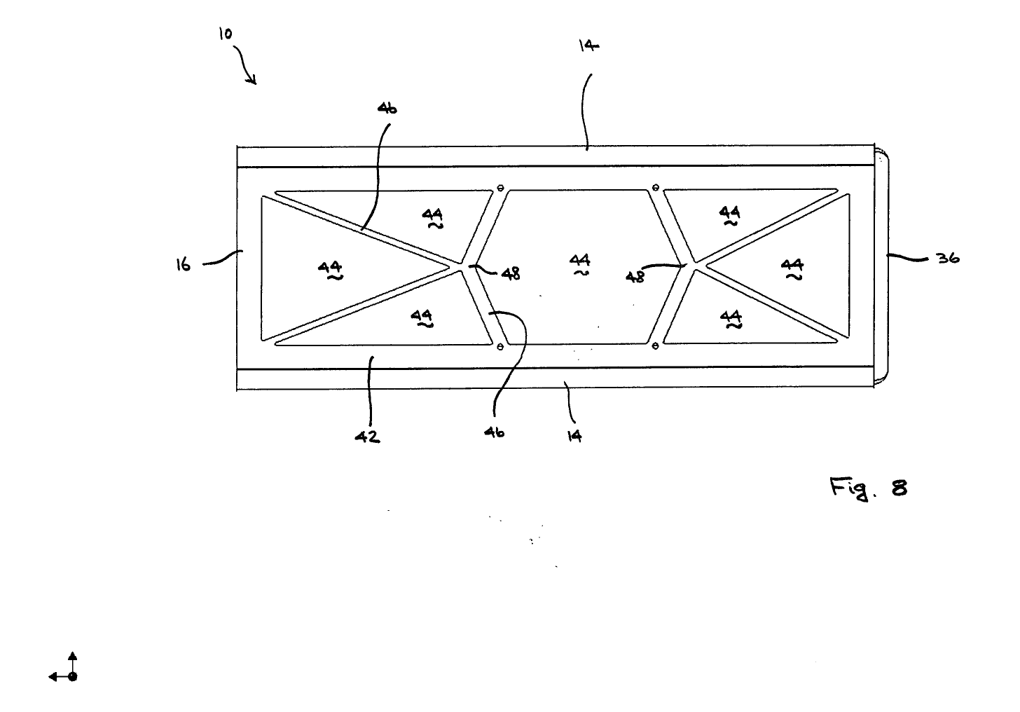

FIG. 8 is an elevational view taken from above computer chassis 10 and showing top lattice member 16. Bottom lattice member 18 may have exactly the same appearance. Top and bottom lattice members 16, 18; right and left lattice members 20, 22, shown, for example, in FIGS. 1, 3 and 4; and motherboard lattice member 34, shown most clearly in FIG. 4, may be generally described as follows, using top lattice member 16 shown in FIG. 8 as a reference. Top lattice member 16 has an unbroken perimetric border 42 surrounding a plurality of open areas 44 produced when punching top lattice member 16 from sheet material of aluminum, plastic or other material. The open areas 44 are separated from one another by struts 46, which may connect points on opposite sides of perimetric border 42 or which may connect points on the perimetric border 42 to points within the perimetric border 42, such as points 48 in top lattice member 16. Struts 46 provide top lattice member 16 with structural stability against forces acting thereupon in the plane thereof. It may be seen in FIG. 8 that open areas 44 make up a substantial portion of the total area of the top lattice member 16, the total area being determined by the outer dimensions of perimetric border 42 and including open areas 44. Preferably, the open areas 44 represent at least 50% of the total area of the top lattice member 16. More preferably, the open areas 44 represent 50% to 60% of the total area of the top lattice member 16. Even more preferably, open areas 44 represent over 60% of the total area of the top lattice member 16. As stated above, bottom lattice member 18 may have the same appearance as top lattice member 16, but this is not specifically required.

Referring now to FIG. 4, right lattice member 22 has struts 52 which connect points on opposite sides of unbroken perimetric border 54. Struts 52 intersect one another at points 56 and form a plurality of “X” shapes on the right lattice member 22. As before, open areas 58 make up a substantial portion of the total area of the right lattice member 22, with the total area again being determined by the outer dimensions of perimetric border 54 and including open areas 58. Preferably, the open areas 58 represent at least 50% of the total area, and, more preferably, the open areas 58 represent 50% to 60% of the total area of the right lattice member 22. Even more preferably, open areas 58 represent over 60% of the total area of the right lattice member 22. Left lattice member 20 may have the same appearance as right lattice member 22, but this is not specifically required. It will finally be noted that openings 60 are provided on struts 56, so that various computer components may ultimately be secured within computer chassis 10.

Still referring to FIG. 4, motherboard lattice member 34 also shares these general characteristics. Unbroken perimetric border 62 has points connected to one another by struts 64 which intersect with one another at point 66 to form an “X” shape. Other struts 68 connect points on opposite sides of perimetric border 62 and intersect with other struts 70 at points 72 to form a grid-like pattern. Holes 74 are provided at multiple locations so that a motherboard and other components may be mounted within the computer chassis 10. Again, open areas 76 make up a substantial portion of the total area of the motherboard lattice member 34, with the total area being determined by the outer dimension of the perimetric border 62 and including open areas 76. Preferably, the open areas 76 represent at least 50% of the total area, and, more preferably, the open areas 76 represent 50% to 60% of the total area of the motherboard lattice member 34. Even more preferably, open areas 76 represent over 60% of the total area of the motherboard lattice member 34.

As for rear lattice member 36, as best seen in FIG. 5, this also has a plurality of open areas 78, some of which are separated from others by struts 80 which intersect with one another and form “X” shapes. As previously noted, edge 38 is bent or curved for attachment to fins 24, 30 of lower and upper frame members 12, 14, respectively, and rear lattice member 36 may be integrally formed with motherboard lattice member 34. As before, holes 82 are provided to facilitate the attachment of components within the computer chassis 10. Finally, and as before, open areas 78 make up a substantial portion of the total area of the rear lattice member 36, that being the substantially planar portion exclusive of the curved sections between the rear lattice member 36 and motherboard lattice member 34 and edge 38. Preferably, the open areas 78 represent at least 50% of the total area, and, more preferably, the open areas 78 represent 50% to 60% of the total area of the rear lattice member 36. Even more preferably, the open areas 78 represent over 60% of the total area of the rear lattice member 36.

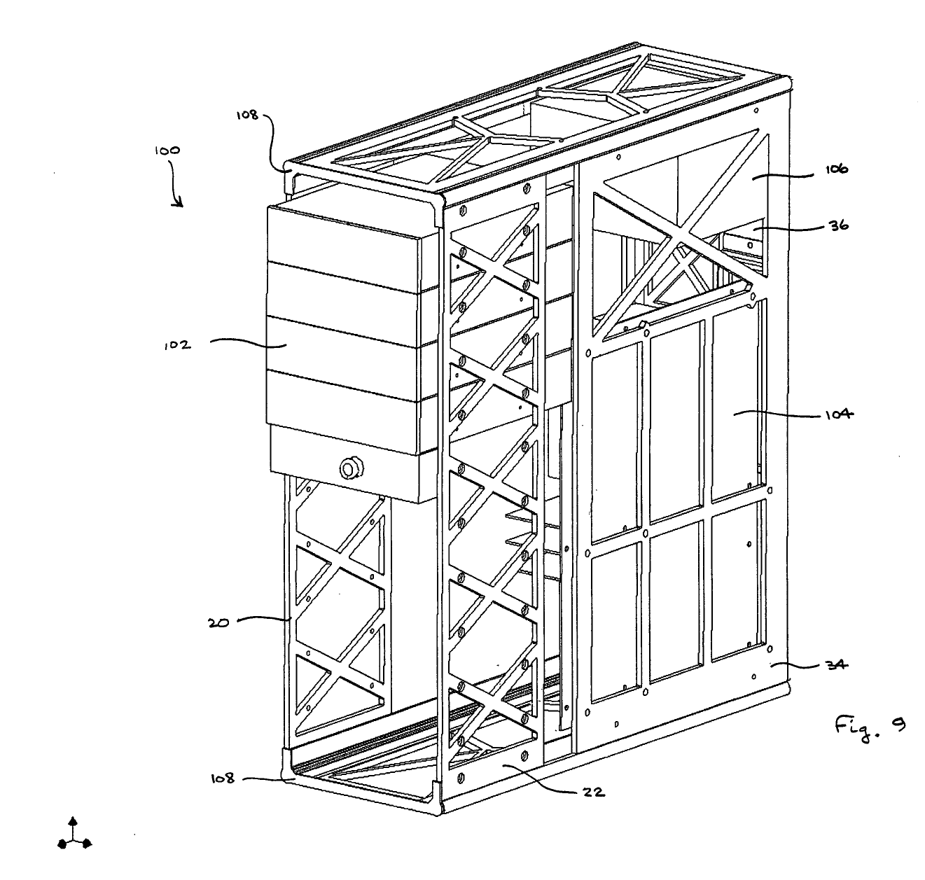

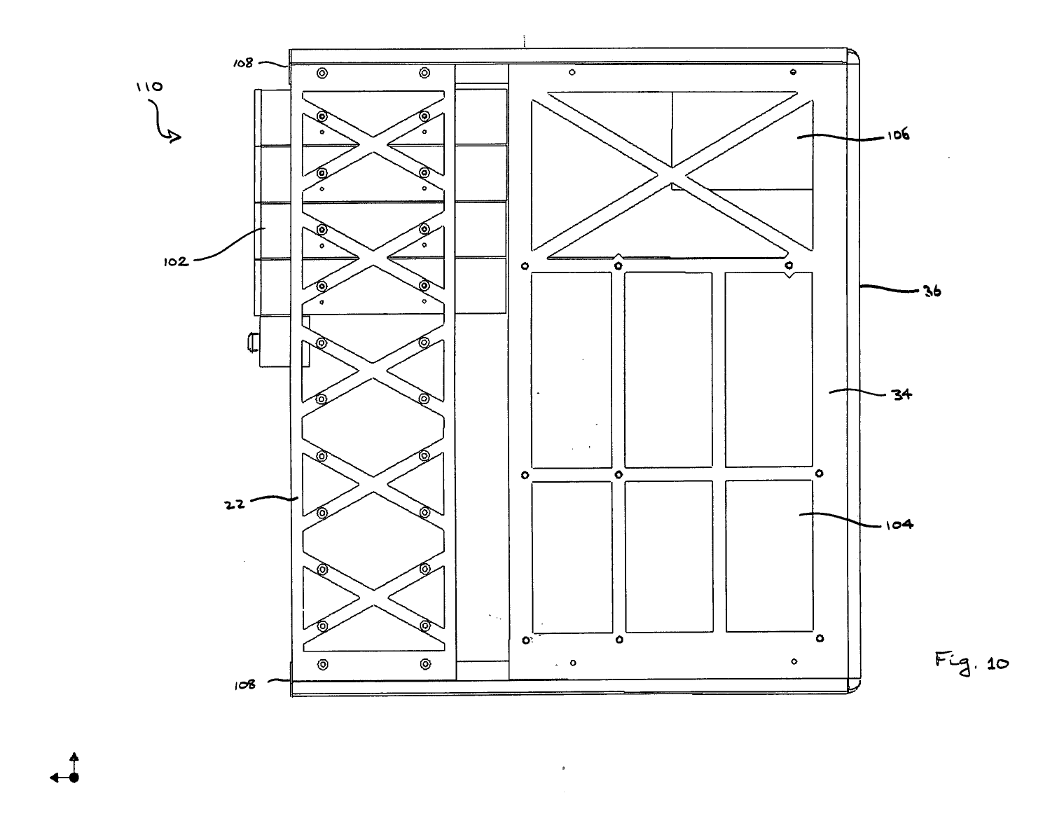

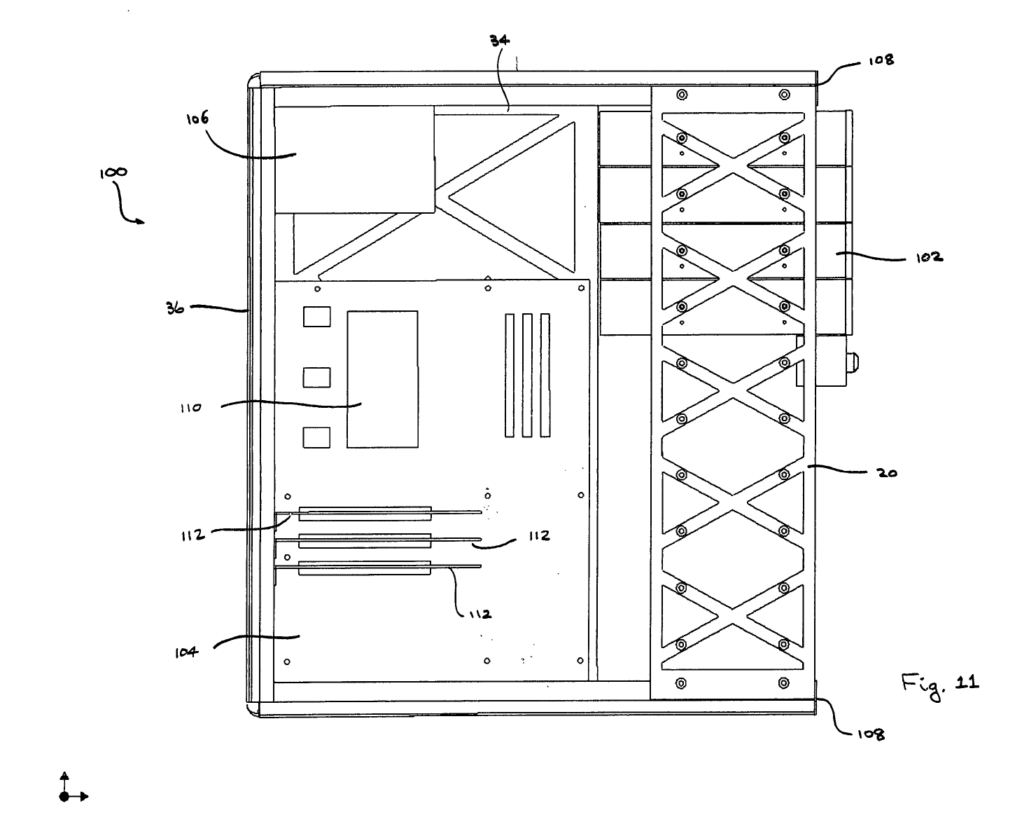

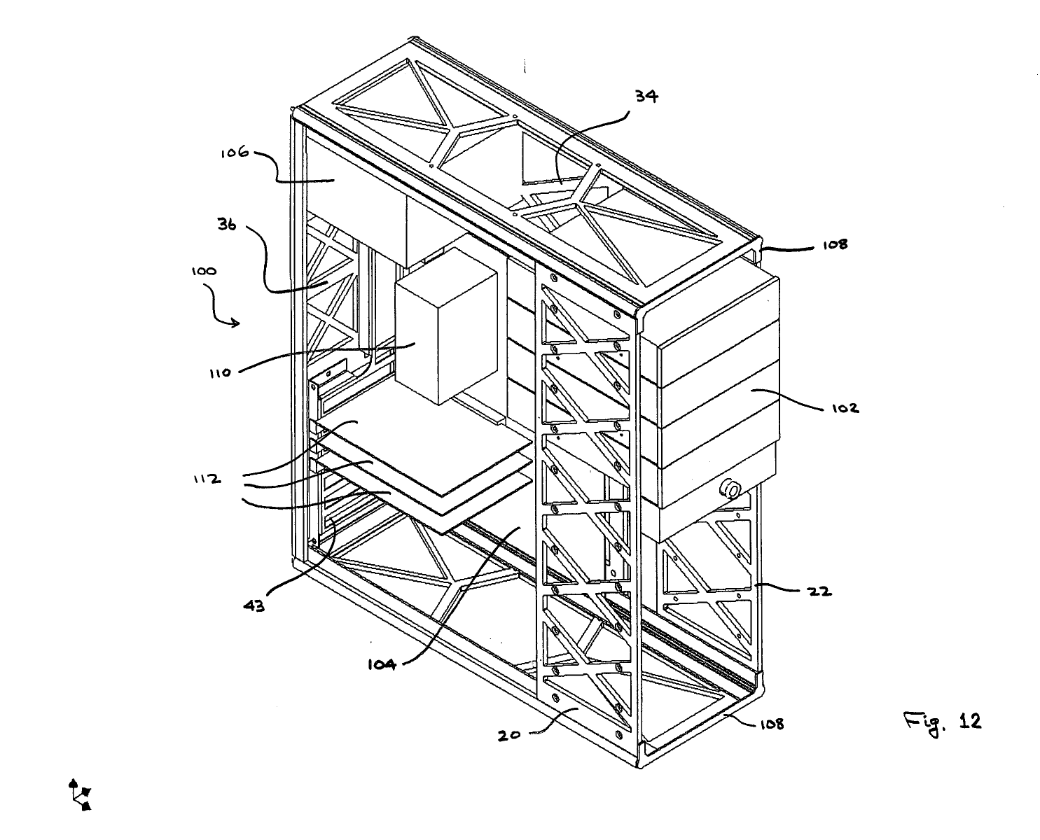

For purposes of illustration, FIGS. 9 through 12 show the use of the computer chassis 10 of the present invention for the assembly of a computer 100. FIG. 9 is a perspective view of the computer 100 from above and to the right thereof; FIG. 10 is an elevational view of the right side of the computer 100; FIG. 11 is an elevational view of the left side of the computer 100; and FIG. 12 is a perspective view of the computer 100 from above and to the left thereof.

Referring to FIGS. 9 through 12, several disc drives 102 are installed between the left and right lattice members 20, 22. Motherboard 104, seen from behind in FIGS. 9 and 10, and from in front in FIGS. 11 and 12, is mounted on motherboard lattice member 34. Power supply 106, which has a built-in fan, is mounted on rear lattice member 36. Decorative members 108 may be provided across the top and bottom of the front of computer chassis 10 for aesthetic purposes. Processor 110 is mounted on motherboard 104. Expansion boards 112, perhaps providing additional memory, are also mounted on motherboard 104 through expansion slots 43. An additional fan may be mounted on the inside of the rear lattice member 36 in a position communicating with one or more open areas 78. For the sake of simplicity, wiring and other details have been omitted from FIGS. 9 through 12, as will readily be apparent from those of ordinary skill in the art.

The following examples illustrate the calculation of the open area percentages for the lattice members of the present computer chassis.

### EXAMPLE I

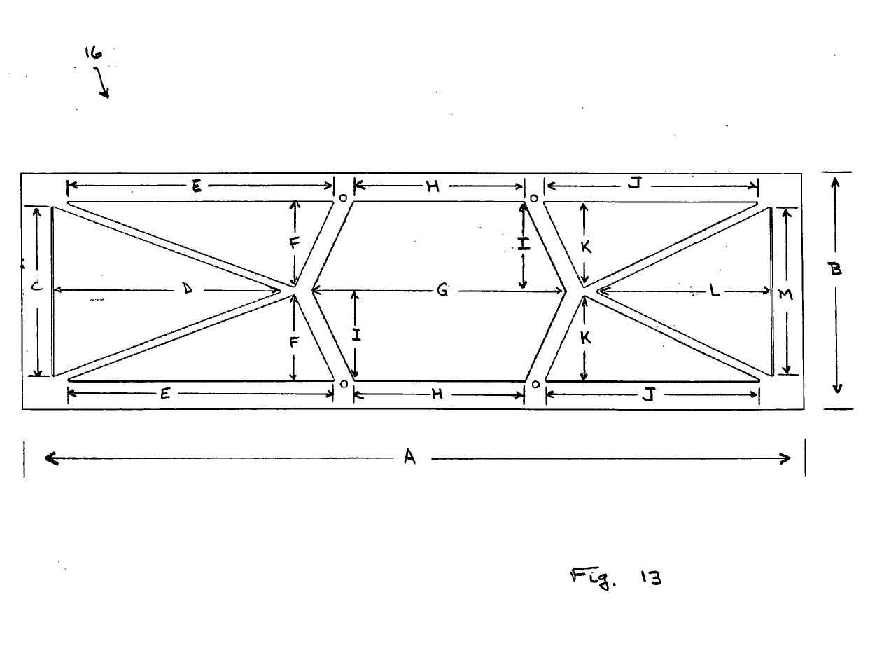

FIG. 13 is an elevational view of the top lattice member 16 of the computer chassis 10. The straight line segments indicated in FIG. 13 have the values indicated in the table below.

| Segment | Length (inches) |
|---|---|
| A | 16.9 |
| B | 5.0 |
| C | 3.7 |
| D | 5.0 |
| E | 5.7 |
| F | 1.9 |
| G | 5.5 |
| H | 3.7 |
| I | 2.0 |
| J | 4.6 |
| K | 1.9 |
| L | 3.8 |
| M | 3.7 |

Based on these measurements, the total area, including open areas, of the top lattice member 16 is A×B, which is equal to 84.5 square inches.

The total area represented by the open areas, exclusive of any holes that may be provided for screws or the like, is ½C×D+2(½E×F)+2(½(G+H)×I)+2(½J×K)+½L×M. This is equal to 9.25 square inches+10.83 square inches+18.4 square inches+8.74 square inches+7.03 square inches for a total open area of 54.25 square inches.

Accordingly, the open areas of the top lattice member 16 make up (54.25/84.5)×100%, that is, 64.2% of its total area.

### EXAMPLE II

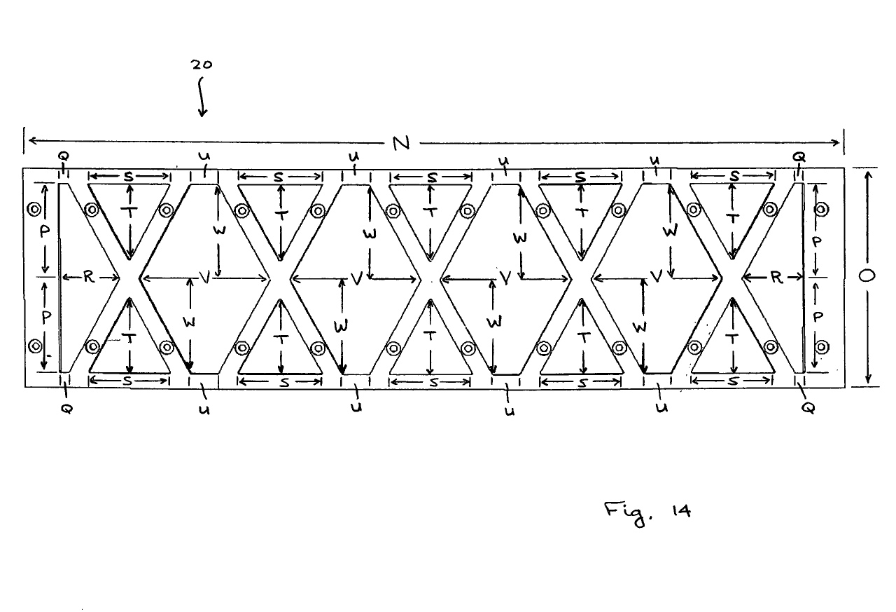

FIG. 14 is an elevational view of the left lattice member 20 of the computer chassis 10. The straight line segments indicated in FIG. 14 have the values indicated in the table below.

| Segment | Length (inches) |
|---|---|
| N | 18.2 |
| O | 5.0 |
| P | 2.125 |
| Q | 0.16 |
| R | 1.4 |
| S | 1.79 |
| T | 1.7 |
| U | 0.57 |
| V | 2.9 |
| w | 2.125 |

Based on these measurements, the total area, including open areas, of the left lattice member 20 is N×O, which is equal to 91.0 square inches.

The total area represented by the open areas, exclusive of any holes that may be provided for screws or the like, is 2×2(½P×(Q+R))+10(½S×T)+4×2(½(U+V)×W). This is equal to 6.63 square inches+15.215 square inches+29.495 square inches for a total open area of 51.34 square inches.

Accordingly, the open areas of the left lattice member 20 make up (51.34/91.0)×100%, that is, 56.4% of its total area.

Modifications to the above would be obvious to those of ordinary skill in the art, but would not bring the invention so modified beyond the scope of the appended claims.

What is claimed is:

1. A computer chassis, said computer chassis being a box-like container, wherein computer components are installed to assemble a computer, said computer chassis having a top, a bottom, a left side and a right side, a rear and an open front, said computer chassis comprising:
a top member, said top member forming said top of said computer chassis;
a bottom member, said bottom member forming said bottom of said computer chassis;
a left member and a right member, said left and right members forming at least a portion of said left and right sides, respectively, of said computer chassis, said left and right members, together with said top and bottom members, framing said open front of said computer chassis;
a motherboard member, said motherboard member forming a portion of one of said left and right sides of said computer chassis; and
a rear member, said rear member forming said rear of said computer chassis,
wherein said top, bottom, left, right, motherboard and rear members are of sheet material, and
wherein at least one of said top, bottom, left, right, motherboard and rear members is a lattice member including a plurality of open areas, said open areas making up a substantial portion of the total area of said lattice member.

2. A computer chassis as claimed in claim 1 wherein said open areas represent at least 50% of the total area of said lattice member.

3. A computer chassis as claimed in claim 1 wherein said open areas represent 50% to 60% of the total area of said lattice member.

4. A computer chassis as claimed in claim 1 wherein said open areas represent over 60% of the total area of said lattice member.

5. A computer chassis as claimed in claim 1 wherein said lattice member includes a perimetric border and a plurality of struts defining said open areas within said perimetric border.

6. A computer chassis as claimed in claim 5 wherein at least one of said struts connects points on opposite sides of said perimetric border.

7. A computer chassis as claimed in claim 5 wherein at least one of said struts connects with another of said struts within said perimetric border.

8. A computer chassis as claimed in claim 1 comprising a first upper frame member and a second upper frame member, said first upper frame member connecting said top member to said left member and said second upper frame member connecting said top member to said right member.

9. A computer chassis as claimed in claim 1 comprising a first lower frame member and a second lower frame member, said first lower frame member connecting said bottom member to said left member and said second lower frame member connecting said bottom member to said right member.

10. A computer chassis as claimed in claim 1 wherein said motherboard member is integrally formed with said rear member.

11. A computer chassis as claimed in claim 1 wherein said sheet material is of aluminum.

12. A computer chassis as claimed in claim 1 wherein said sheet material is of plastic.

13. A computer chassis as claimed in claim 8 wherein said first and second upper frame members are of aluminum.

14. A computer chassis as claimed in claim 8 wherein said first and second upper frame members are of plastic.

15. A computer chassis as claimed in claim 9 wherein said first and second lower frame members are of aluminum.

16. A computer chassis as claimed in claim 9 wherein said first and second lower frame members are of plastic.

17. A computer chassis as claimed in claim 1 wherein said motherboard member and one of said left and right members are integrally formed with one another.
